(19) United States
(12) Patent Application Publication
(10) Pub. No.: US 2012/0037951 A1
(43) Pub. Date: Feb. 16, 2012

(54) Optical Device And Method Of Producing The Same

(76) Inventor: Masayoshi Terada, Chiba-shi (JP)

(21) Appl. No.: 13/263,668

(22) PCT Filed: Apr. 6, 2010
(86) PCT No.: PCT/JP2010/056495

§ 371 Date: Oct. 7, 2011

(30) Foreign Application Priority Data
Apr. 10, 2009 (JP) 2009-095611

(51) Int. Cl. H01L 33/56; H01L 33/54; H01L 31/18; H01L 31/0203

(52) U.S. Cl. 257/100; 257/433; 438/26; 438/64; 257/E33.059; 257/E31.117; 257/E33.06; 257/E31.119

(57) ABSTRACT

An optical device of the present invention comprises a light-emitting element or a light-receiving element mounted on a support and a cured silicone material unified into a single article onto the support by the sealing of the element with a hydrosilylation reaction curable silicone composition, and is characterized in that the surface of the cured silicone material has been treated with an organopolysiloxane that has at least three silicon-bonded hydrogen atoms in one molecule. The optical device is resistant to the adherence of dust and dirt due to an inhibition of the stickiness of the surface of a cured silicone material that seals a light-emitting element or a light-receiving element mounted on a support and has thereby been unified into a single body onto the support.

### TECHNICAL FIELD

The present invention relates to an optical device in which a cured silicone material is unified into a single article therein with a light-emitting element or a light-receiving element that is mounted on a support. The present invention further relates to a method of producing this optical device.

### BACKGROUND ART

An optical device provided by sealing a support-mounted light-emitting element, e.g., an LED chip, with a curable silicone composition to yield the support unified into a single article with a cured silicone material is known. In an example of a method for producing such an optical device, a mold that has a concave cavity opposite the position of the support-mounted LED chip is coated with a very thin release film; a curable silicone composition is then filled into the concave cavity; and the LED chip-bearing support is subsequently pressed against the mold and the composition is cured (refer to Japanese Unexamined Patent Application Publications 2005-305954, 2006-148147 and 2008-227119).

In order in the preceding method to satisfactorily relax the stresses on the LED chip, a curable silicone composition is preferably used that provides a cured material in the form of a gel or a low-hardness rubber. However, a problem here is that the surface of the resulting cured silicone material is quite sticky, which results in the adherence of dust and dirt and thus produces a deficient appearance.

It is an object of the present invention is to provide an optical device that resists the adherence of dust and dirt due to an inhibition of the stickiness of the surface of the cured silicone material that has become unified into a single article therein by the sealing of a light-emitting element or a light-receiving element mounted on a support. An additional object of the present invention is to provide an efficient method of producing this optical device.

### DISCLOSURE OF INVENTION

The optical device of the present invention is an optical device that comprises a light-emitting element or a light-receiving element mounted on a support and a cured silicone material unified into a single article onto the support by the sealing of the element with a hydrosilylation reaction curable silicone composition, and is characterized in that the surface of the cured silicone material has been treated with an organopolysiloxane that has at least three silicon-bonded hydrogen atoms in one molecule.

This organopolysiloxane is preferably a methylhydrogenpolysiloxane endblocked at both molecular chain terminals by the trimethylsiloxy groups, a copolymer of dimethylsiloxane and methylhydrogensiloxane endblocked at both molecular chain terminals by the trimethylsiloxy groups, or a polysiloxane comprising the unit represented by the formula: SiO_{4/2} and the unit represented by the formula: H(CH₃)₂SiO_{1/2}.

In addition, the cured silicone material preferably has the shape of a convex lens.

The method of the present invention for producing an optical device is a method of producing an optical device that has a cured silicone material unified therewith by filling a hydrosilylation reaction curable silicone composition onto a release film in a mold, wherein the mold has a cavity positioned opposite a light-emitting element or a light-receiving element that is mounted on a support and the mold is in intimate contact with the release film wherein the release film is deformed into the shape of the cavity, and by then molding the composition with the support pressed against the mold, said method being characterized by preliminarily coating an organopolysiloxane that has at least three silicon-bonded hydrogen atoms in one molecule on the surface of the release film that will come into contact with the composition.

The release film in this method is preferably a fluororesin film, a polyester resin film, or a polyolefin resin film.

The organopolysiloxane in this method is preferably a methylhydrogenpolysiloxane endblocked at both molecular chain terminals by the trimethylsiloxy groups, a copolymer of dimethylsiloxane and methylhydrogensiloxane endblocked at both molecular chain terminals by the trimethylsiloxy groups, or a polysiloxane comprising the unit represented by the formula: SiO_{4/2} and the unit represented by the formula: H(CH₃)₂SiO_{1/2}. In addition, the rate of coating by this organopolysiloxane is preferably 0.01 to 10 g per 1 m².

### EFFECTS OF INVENTION

The optical device of the present invention characteristically resists the adherence of dust and dirt due to an inhibition of the stickiness of the surface of the cured silicone material that has become unified into a single article therein by the sealing of the light-emitting element or light-receiving element mounted on the support. The production method of the present invention is characteristically able to efficiently produce this optical device.

### BRIEF DESCRIPTION OF THE DRAWINGS

FIG. 1 is a cross-sectional partial cutaway diagram that shows an optical device prior to the formation of the cured silicone material.

FIG. 2 is a cross-sectional partial cutaway diagram that shows the state prior to filling with the hydrosilylation reaction curable silicone composition.

FIG. 3 is a cross-sectional partial cutaway diagram that shows the state after filling with the hydrosilylation curable silicone composition.

FIG. 4 is a cross-sectional partial cutaway diagram that shows the hydrosilylation reaction curable silicone composition being molded.

FIG. 5 is a cross-sectional partial cutaway diagram that shows an optical device that has been unified into a single article with a cured silicone material.

FIG. 6 is a cross-sectional partial cutaway diagram that shows another optical device that has been unified into a single article with a cured silicone material.

FIG. 7 is a cross-sectional partial cutaway diagram that shows another optical device that has been unified into a single article with a cured silicone material.

### REFERENCE NUMERALS USED IN THE DESCRIPTION

1 support

2 LED chip

3 bonding wire

4 mold

5 release film

6 hydrosilylation reaction curable silicone composition

7 cured silicone material

### DETAILED DESCRIPTION OF THE INVENTION

The optical device of the present invention contains a light-emitting element or a light-receiving element mounted on a support and also contains a cured silicone material unified into a single article therein by the sealing of the element with a hydrosilylation reaction curable silicone composition. The light-emitting element can be exemplified by light-emitting diode (LED) chips. The LED chip is suitably an LED chip provided by forming a semiconductor such as InN, AlN, GaN, ZnSe, SiC, GaP, GaAs, GaAlAs, GaAlN, AlInGaP, InGaN, AlInGaN, and so forth, as a light-emitting layer on a substrate by a liquid-phase growth method or an MOCVD method.

The support can be exemplified by ceramic substrates, silicon substrates, and metal substrates and by organic resin substrates of, for example, a polyimide resin, an epoxy resin, a BT resin, and so forth. In addition to the light-emitting element or light-receiving element mounted on the support, the support may also have, inter alia, an electrical circuit, a bonding wire, e.g., a gold or aluminum wire, in order to electrically connect this circuit to the LED chip, and an outer lead for the circuit. The optical devices shown in FIGS. 5 to 7 are populated with a plurality of LED chips, but separate optical devices may be elaborated by cutting or breaking the support.

The cured silicone material is formed as a unified article when sealing of the light-emitting element or light-receiving element with a hydrosilylation reaction curable silicone composition is performed and preferably adheres to the support and the light-emitting element or light-receiving element. This cured silicone material may be a transparent cured material or may be a cured material that contains, for example, a fluorescent substance. The shape of this cured silicone material is not particularly limited and can be exemplified by convex lens shaped, truncated cone shaped, and truncated quadrangular pyramid shaped, wherein convex lens shaped is preferred.

The hydrosilylation reaction curable silicone composition that forms this cured silicone material generally comprises an organopolysiloxane that has at least two alkenyl groups in one molecule, an organopolysiloxane that has at least two silicon-bonded hydrogen atoms in one molecule, and a hydrosilylation reaction catalyst; is preferably a transparent fluid; and as necessary may incorporate an inorganic filler, a fluorescent substance, and so forth. The viscosity of this curable silicone composition is not particularly limited, but the composition is preferably a fluid in the range of 0.1 to 200 Pa·s at 25° C. and more preferably a fluid in the range of 0.1 to 30 Pa·s at 25° C. Such curable silicone compositions are generally commercially available, for example, as SE1896FR from Dow Corning Toray Co., Ltd.

When the cured silicone material is formed in the optical device of the present invention by the sealing of the light-emitting element or light-receiving element by the hydrosilylation reaction curable silicone composition, the treatment with an organopolysiloxane that has at least three silicon-bonded hydrogen atoms in one molecule results in an increase in the crosslink density at the surface of the cured silicone material and in an inhibition of the tack at this surface and thus will prevent the adherence of dust and dirt. This organopolysiloxane is to have at least three silicon-bonded hydrogen atoms in one molecule, but is not otherwise particularly limited. The silicon-bonded groups in this organopolysiloxane can be specifically exemplified by substituted and unsubstituted monovalent hydrocarbyl groups, e.g., alkyl groups such as methyl, ethyl, propyl, isopropyl, butyl, isobutyl, t-butyl, pentyl, hexyl, cyclohexyl, heptyl, octyl, nonyl, decyl, and so forth; alkenyl groups such as vinyl, allyl, isopropenyl, butenyl, isobutenyl, hexenyl, cyclohexenyl, and so forth; aryl groups such as phenyl, tolyl, xylyl, naphthyl, and so forth; aralkyl groups such as benzyl, phenethyl, and so forth; and halogen-substituted alkyl groups such as 3-chloropropyl, 3,3,3-trifluoropropyl, and so forth; wherein monovalent hydrocarbyl lacking the aliphatically unsaturated carbon-carbon bond is preferred.

There are no limitations on the molecular structure of this organopolysiloxane, and its molecular structure is exemplified by straight chain, partially branched straight chain, branched chain, dendritic, network, and cyclic. Its viscosity at 25° C. is preferably in the range from 1 to 1,000 mPa·s, is more preferably in the range from 1 to 500 mPa·s, and is particularly preferably in the range from 1 to 100 mPa·s.

This organopolysiloxane can be exemplified by methylhydrogenpolysiloxane endblocked at both molecular chain terminals by the trimethylsiloxy groups; copolymer of dimethylsiloxane and methylhydrogensiloxane endblocked at both molecular chain terminals by the trimethylsiloxy groups; methylhydrogenpolysiloxane endblocked at both molecular chain terminals by the dimethylhydrogensiloxy groups; copolymer of dimethylsiloxane and methylhydrogensiloxane endblocked at both molecular chain terminals by the dimethylhydrogensiloxy groups; cyclic methylhydrogensiloxane; cyclic copolymer of dimethylsiloxane and methylhydrogensiloxane; copolymer comprising the siloxane unit represented by the formula: (CH₃)₃SiO_{1/2}, the siloxane unit represented by the formula: H(CH₃)₂SiO_{1/2}, and the siloxane unit represented by the formula: SiO_{4/2}; copolymer comprising the siloxane unit represented by the formula: H(CH₃)₂SiO_{1/2} and the siloxane unit represented by the formula: SiO_{4/2}; copolymer comprising the siloxane unit represented by the formula: (CH₃)₃SiO_{1/2}, the siloxane unit represented by the formula: H(CH₃)₂SiO_{1/2}, the siloxane unit represented by the formula: (CH₃)₂SiO_{2/2}, and the siloxane unit represented by the formula SiO_{4/2}; and mixtures of two or more of the preceding. Methylhydrogenpolysiloxane endblocked at both molecular chain terminals by the trimethylsiloxy groups, copolymer of dimethylsiloxane and methylhydrogensiloxane endblocked at both molecular chain terminals by the trimethylsiloxy groups, and polysiloxane comprising the unit represented by the formula: SiO_{4/2} and the unit represented by the formula: H(CH₃)₂SiO_{1/2} are particularly preferred.

An example of a method for producing this optical device is the method of producing an optical device having a cured silicone material unified therewith by filling a hydrosilylation reaction curable silicone composition onto a release film in a mold, wherein the mold has a cavity positioned opposite a light-emitting element or a light-receiving element mounted on a support and the mold is in intimate contact with the release film wherein the release film has been deformed into the shape of the cavity, and by then molding the composition with the support pressed against the mold. The method according to the present invention is characterized by preliminarily coating an organopolysiloxane that has at least three silicon-bonded hydrogen atoms in one molecule on the surface of the release film that in the aforementioned method will come into contact with the curable silicone composition.

The present method uses a molding device that can mold the cured silicone material while sealing the support-mounted light-emitting element or light-receiving element with the hydrosilylation reaction curable silicone composition. The commonly used molding devices can be used as this molding device. A molding device that has an air suction mechanism in the mold is preferred for the purpose of bringing the release film into intimate contact with the cavity. This air suction mechanism functions during molding to bring the release film into intimate contact with the cavity and by blowing air functions after molding to peel the release film from the mold and to facilitate removal of the molded article.

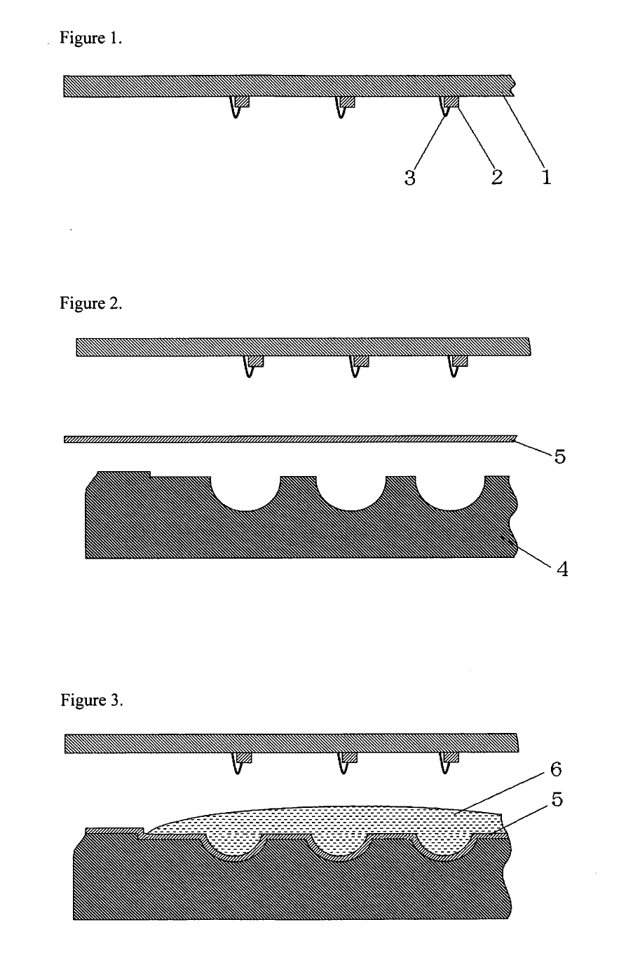

The present method will be described with reference to the drawings. FIG. 1 is a cross-sectional partial cutaway diagram that shows an optical device prior to the formation of the cured silicone material. In FIG. 1, an LED chip 2 is mounted by, for example, a die bonding agent, on a support 1, and this LED chip 2 is electrically connected by a bonding wire 3 with an outer lead or a circuit (neither is shown in the figure) formed on the surface of the support 1.

FIG. 2 is a cross-sectional partial cutaway diagram that shows the state prior to filling with the hydrosilylation reaction curable silicone composition. The support 1 populated with the LED chips 2 is brought into a position opposite the positions of the cavities in a mold 4. A release film 5 that has been pre-coated with the organopolysiloxane that contains at least three silicon-bonded hydrogens in one molecule is then fed in between the support 1 and the mold 4 and is brought into intimate contact with the mold cavity by an air suction mechanism (not shown in the figure) disposed in the mold 4. FIG. 3 is a cross-sectional partial cutaway diagram that shows the state immediately after a hydrosilylation reaction curable silicone composition 6 has been introduced into the release film 5-covered mold 4.

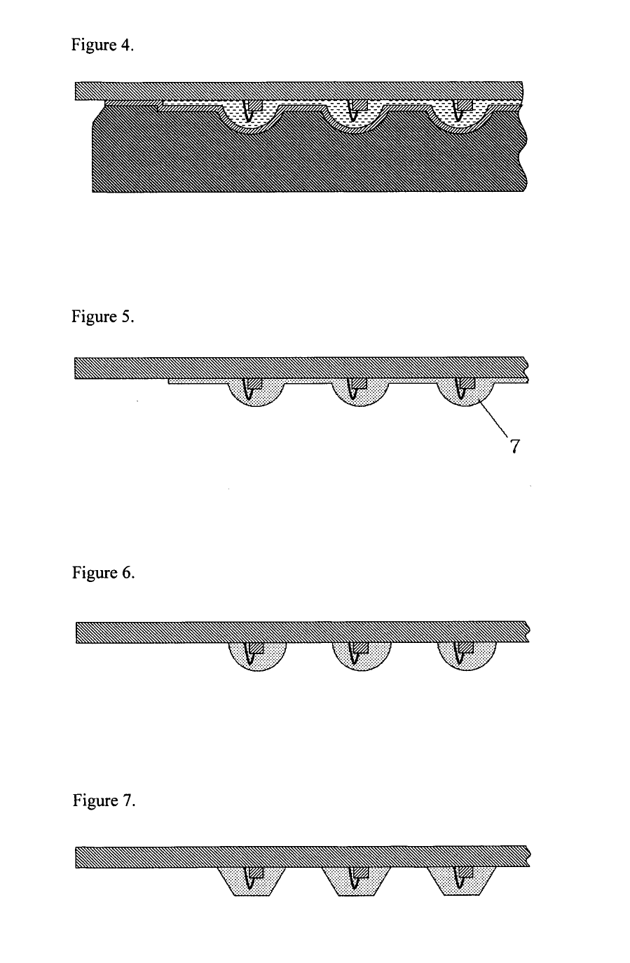

FIG. 4 is a cross-sectional partial cutaway diagram that shows the hydrosilylation reaction curable silicone composition being molded. By pressing the support 1 against the mold 4, the release film 5 can be sandwiched and the periphery of the sealed region can be reliably closed off and leakage by the composition can be prevented.

This release film 6 is a release film that can be easily brought into intimate contact with the mold by, for example, air suction, and that exhibits heat resistance sufficient to withstand the curing temperature for the hydrosilylation reaction curable silicone composition. Release films of this nature can be exemplified by fluororesin films such as polytetrafluoroethylene resin (PTFE) films, ethylene-tetrafluoroethylene copolymer resin (ETFE) films, tetrafluoroethylene-perfluoropropylene copolymer resin (FEP) films, polyvinylidene fluoride resin (PBDF) films, and so forth; polyester resin films such as polyethylene terephthalate resin (PET) films and so forth; and fluorine-free polyolefin resin films such as polypropylene resin (PP) films, cycloolefin copolymer resin (COC) films, and so forth. The thickness of this release film is not particularly limited, but approximately 0.01 mm to 0.2 mm is preferred.

The present method is characterized by the coating of an organopolysiloxane having at least three silicon-bonded hydrogens in one molecule on the side of the release film that will come into contact with the hydrosilylation reaction curable silicone composition. This organopolysiloxane is as previously described. The coating rate of this organopolysiloxane is not particularly limited, but an amount that provides 0.01 to 10 g per 1 m² is preferred, while an amount that provides 0.01 to 5 g per 1 m² is more preferred and an amount that provides 0.01 to 2 g per 1 m² is particularly preferred.

The curing conditions for the hydrosilylation reaction curable silicone composition are not particularly limited, but, for example, heating is carried out preferably for about 0.5 to 60 minutes and particularly about 1 to 30 minutes at preferably 50 to 200° C. and particularly 100 to 150° C. As necessary, a secondary cure (post-cure) may be performed for about 0.5 to 4 hours at 150 to 200° C.

FIG. 5 is a cross-sectional partial cutaway diagram that shows an optical device of the present invention having a convex lens of silicone unified therewith. While a plurality of LED chips are mounted in FIG. 5, the optical devices may be singulated by cutting the support using, for example, a dicing saw, laser, and so forth.

### EXAMPLES

The optical device of the present invention and the method of the present invention for producing this optical device are described in detail by examples. The viscosity in the examples is the value at 25° C.

### Practical Example 1

An FFT1005 from the TOWA Corporation was used as the compression molder. An alumina circuit substrate having 256 light-emitting diode (LED) chips mounted thereon was fixed with a clip in the upper mold of this compression molder. A 0.05 mm-thick polyolefin resin film—which had been coated at a coating rate of 0.05 g/m² with a methylhydrogenpolysiloxane that was endblocked at both molecular chain terminals by the trimethylsiloxy groups and had a viscosity of 20 mPa·s and a silicon-bonded hydrogen content of 1.56 weight %—was then introduced onto a mold having a concave cavity as shown in FIG. 2, and the film was brought into intimate contact with the lower mold by an air suction mechanism present in the lower mold. 1.5 g of a hydrosilylation reaction curable silicone gel composition (trade name: SE1896FR, product of Dow Corning Toray Co., Ltd.) having a viscosity of 400 mPa·s was subsequently filled into the concave cavity.

This hydrosilylation reaction curable silicone gel composition had the ability to form a cured gel with a ¼-penetration as prescribed in JIS K 2220 of approximately 60 when heated for 5 minutes at 140° C. The upper and lower molds were closed with the individual concave cavities opposite the individual LED chips mounted on the support and compression molding was performed for 5 minutes at 140° C. The mold was then opened and an optical device unified into a single article with convex silicone lenses was removed. The silicone lens surfaces of this optical device were hard and exhibited little tack and also did not undergo fingerprint transfer.

### Practical Example 2

An optical device was produced as in Example 1, but in this case the release film surface treatment in Example 1 was carried out using a coating rate of 0.05 g/m² and a silicone resin that had the average unit formula: [H(CH₃)₂SiO_{1/2}]_{1.6}(SiO_{4/2})_{1.0}, a viscosity of 25 mPa·s, and a silicon-bonded hydrogen content of 0.97% by weight. The silicone lens surfaces of this optical device were hard and exhibited little tack and also did not undergo fingerprint transfer.

### Practical Example 3

An optical device was produced as in Example 1, but in this case the release film surface treatment in Example 1 was carried out using a coating rate of 1.00 g/m² and a silicone resin that had the average unit formula: [H(CH₃)₂SiO_{1/2}]_{1.6}(SiO_{4/2})_{1.0}, a viscosity of 25 mPa·s, and a silicon-bonded hydrogen content of 0.97% by weight. The silicone lens surfaces of this optical device were hard and exhibited little tack and also did not undergo fingerprint transfer.

### Practical Example 4

An optical device was produced as in Example 1, but in this case the release film surface treatment in Example 1 was carried out using a coating rate of 0.05 g/m² and a copolymer of dimethylsiloxane and methylhydrogensiloxane that was endblocked at both molecular chain terminals by the trimethylsiloxy groups and had a viscosity of 63 mPa·s and a silicon-bonded hydrogen content of 0.70% by weight. The silicone lens surfaces of this optical device were hard and exhibited little tack and also did not undergo fingerprint transfer.

### Practical Example 5

An optical device was produced as in Example 1, but in this case the release film surface treatment in Example 1 was carried out using a coating rate of 1.00 g/m² and a copolymer of dimethylsiloxane and methylhydrogensiloxane that was endblocked at both molecular chain terminals by the trimethylsiloxy groups and had a viscosity of 63 mPa·s and a silicon-bonded hydrogen content of 0.70% by weight. The silicone lens surfaces of this optical device were hard and exhibited little tack and also did not undergo fingerprint transfer.

### Comparative Example 1

An optical device was produced as in Example 1, but in this case omitting the release film surface treatment in Example 1 with the methylhydrogenpolysiloxane that was endblocked at both molecular chain terminals by the trimethylsiloxy groups and had a viscosity of 20 mPa·s and a silicon-bonded hydrogen content of 1.56% by weight. The silicone lens surfaces of this optical device were strongly tacky and underwent fingerprint transfer.

### INDUSTRIAL APPLICABILITY

The optical device of the present invention, because it is resistant to the adherence of dust and dirt due to an inhibition of the stickiness of the surface of the cured silicone material that seals the light-emitting element or light-receiving element mounted on the support and that is thereby unified onto the support, is well suited as an optical device for which reliability, e.g., heat resistance and so forth, is critical.

1. An optical device comprising a light-emitting element or a light-receiving element mounted on a support and a cured silicone material unified into a single article onto the support by the sealing of the element with a hydrosilylation reaction curable silicone composition, the optical device being characterized in that the surface of the cured silicone material has been treated with an organopolysiloxane that has at least three silicon-bonded hydrogen atoms in one molecule.

2. The optical device according to claim 1, wherein the organopolysiloxane is a methylhydrogenpolysiloxane endblocked at both molecular chain terminals by the trimethylsiloxy groups, a copolymer of dimethylsiloxane and methylhydrogensiloxane endblocked at both molecular chain terminals by the trimethylsiloxy groups, or a polysiloxane comprising the unit represented by the formula: SiO_{4/2} and the unit represented by the formula: H(CH₃)₂SiO_{1/2}.

3. The optical device according to claim 1, wherein the cured silicone material has the shape of a convex lens.

4. A method of producing an optical device that has a cured silicone material unified therewith by filling a hydrosilylation reaction curable silicone composition onto a release film in a mold, wherein the mold has a cavity positioned opposite a light-emitting element or a light-receiving element that is mounted on a support and the mold is in intimate contact with the release film wherein the release film is deformed into the shape of the cavity, and by then molding the composition with the support pressed against the mold, the method of producing an optical device being characterized by preliminarily coating an organopolysiloxane that has at least three silicon-bonded hydrogen atoms in one molecule on the surface of the release film that will come into contact with the composition.

5. The method of producing an optical device according to claim 4, wherein the release film is a fluororesin film, a polyester resin film, or a polyolefin resin film.

6. The method of producing an optical device according to claim 4, wherein the organopolysiloxane is a methylhydrogenpolysiloxane endblocked at both molecular chain terminals by the trimethylsiloxy groups, a copolymer of dimethylsiloxane and methylhydrogensiloxane endblocked at both molecular chain terminals by the trimethylsiloxy groups, or a polysiloxane comprising the unit represented by the formula: SiO_{4/2} and the unit represented by the formula: H(CH₃)₂SiO_{1/2}.

7. The method of producing an optical device according to claim 4, wherein the rate of coating by the organopolysiloxane is 0.01 to 10 g per 1 m².
